(19) United States
(12) Patent Application Publication
(10) Pub. No.: US 2017/0066343 A1
(43) Pub. Date: Mar. 9, 2017

(54) VOLTAGE MONITORING SYSTEM

(71) Applicant: TOYOTA JIDOSHA KABUSHIKI KAISHA, Toyota-shi (JP)

(72) Inventors: Keiji KAITA, Miyoshi-shi (JP); Akinobu MURAKAMI, Miyoshi-shi (JP); Hironobu KAWASHIMA, Toyota-shi (JP)

(73) Assignee: TOYOTA JIDOSHA KABUSHIKI KAISHA, Toyota-shi (JP)

(21) Appl. No.: 15/254,698

(22) Filed: Sep. 1, 2016

(30) Foreign Application Priority Data
Sep. 4, 2015 (JP) 2015-174474

(51) Int. Cl. B60L 11/18; G01R 31/36

(52) U.S. Cl. CPC B60L 11/1861; G01R 31/362; G01R 31/3658

(57) ABSTRACT

A voltage monitoring system includes a first connection line group connected to input terminals of a first monitoring IC, a first connector configured to connect or disconnect connection lines of the first connection line group to or from connection points each arranged on a side of a positive electrode or negative electrode of any one of battery cells of a first battery group, a second connection line group connected to input terminals of a second monitoring IC, and a second connector configured to connect or disconnect connection lines of the second connection line group to or from connection points arranged on a side of a positive electrode or negative electrode of any one of battery cells of a second battery group. The first monitoring IC is electrically isolated from the second monitoring IC. The first connection line group is electrically isolated from the second connection line group.

### INCORPORATION BY REFERENCE

The disclosure of Japanese Patent Application No. 2015-174474 filed on Sep. 4, 2015 including the specification, drawings and abstract is incorporated herein by reference in its entirety.

### BACKGROUND OF THE INVENTION

1. Field of the Invention

The invention relates to the structure of a voltage monitoring system.

2. Description of Related Art

A battery in which several tens or more of battery cells (for example, lithium ion batteries) each having an output voltage of 3 V to 4 V are serially connected to provide an output voltage of 200 V to 400 V is mounted as a battery that is used in an electromotive vehicle, such as an electric vehicle and a hybrid vehicle. For such a battery in which a large number of battery cells are connected in series with each other, variations in voltage and variations in SOC among the battery cells need to be reduced, so a voltage monitoring system that detects the voltage of each battery cell is used.

A semiconductor (monitoring IC), such as an integrated circuit that is used in a voltage monitoring system, withstands the voltage of several serially connected battery cells each having a voltage of 3 V to 4 V; however, the semiconductor cannot withstand the voltage of several tens of serially connected battery cells. For this reason, a plurality of serially connected battery cells are divided into a plurality of battery groups each having several serially connected battery cells, for example, four to twelve serially connected battery cells, in accordance with the withstanding voltage of the monitoring IC, and then the monitoring IC is provided for each of the plurality of battery groups.

Each of the plurality of monitoring ICs is electrically connected to the positive and negative electrodes of each of a predetermined number of battery cells that are included in a corresponding one of the battery groups, and operates based upon a potential difference (voltage) between the maximum potential and minimum potential of the corresponding one of the battery groups as a power supply voltage. For this reason, power supply lines of the plurality of monitoring ICs are electrically serially connected in accordance with the order of the potentials of the battery groups (see, for example, Japanese Patent Application Publication No. 2013-76602 (JP 2013-076602 A).

In the voltage monitoring system described in JP 2013-076602 A, each of the plurality of monitoring ICs is electrically connected to the battery cells of a corresponding one of the battery groups by fitting a plurality of connectors each connected via wirings to connection points each arranged on the side of the positive electrode or negative electrode of any one of the battery cells to a plurality of connectors provided on a circuit board on which the plurality of monitoring ICs are implemented. The connectors are fitted to each other in a state where the plurality of battery cells are charged. Therefore, at the time of fitting the plurality of connectors, potentials sneak from the monitoring ICs to which the connectors are fitted to the monitoring ICs to which the connectors are not fitted (from which the connectors are disconnected), with the result that the free (non-fitted) connectors have a potential.

This may occur, for example, when the battery group-side connectors are fitted to the monitoring IC-side connectors (live wires are inserted) or when the connectors are connected or disconnected (live wires are inserted or removed) in maintenance of a battery system in a process of manufacturing (assembling) the battery system.

### SUMMARY OF THE INVENTION

It is an object of the invention to, in a battery system including a plurality of battery groups and a plurality of monitoring ICs respectively corresponding to the battery groups, when at least one of a plurality of connectors that are configured to connect or disconnect the corresponding battery groups to or from the corresponding monitoring ICs is disconnected, prevent the at least one disconnected connector from having a potential.

An aspect of the invention provides a voltage monitoring system that monitors each of cell voltages of a battery in which a first battery group and a second battery group are connected in series with each other, the first battery group including a plurality of connected battery cells, the second battery group including a plurality of connected battery cells. The voltage monitoring system includes: a first monitoring IC including a plurality of input terminals; a first connection line group including first connection lines respectively connected to the input terminals of the first monitoring IC; a first connector configured to connect or disconnect the first connection lines of the first connection line group to or from first connection points each arranged on a positive electrode-side or negative electrode-side of any one of the battery cells of the first battery group; a second monitoring IC including a plurality of input terminals, the second monitoring IC being electrically isolated from the first monitoring IC; a second connection line group including second connection lines respectively connected to the input terminals of the second monitoring IC, the second connection line group being electrically isolated from the first connection line group; and a second connector configured to connect or disconnect the second connection lines of the second connection line group to or from second connection points each arranged on a side of a positive electrode or negative electrode of any one of the battery cells of the second battery group.

According to the aspect of the invention, in a battery system including a plurality of battery groups and a plurality of monitoring ICs respectively corresponding to the battery groups, at the time when at least one of a plurality of connectors each configured to connect or disconnect a corresponding one of the battery groups to or from a corresponding one of the monitoring ICs is disconnected, it is possible to prevent the at least one disconnected connector from having a potential.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a system diagram that shows the configuration of a battery system including a voltage monitoring system according to an embodiment of the invention;

FIG. 2 is a view that illustrates a state where one connector is disconnected in the voltage monitoring system according to the embodiment of the invention;

FIG. 3 is a view that illustrates a state where one connector is disconnected in a voltage monitoring system according to a related art; and

FIG. 4 is a view that illustrates a state where one connector is disconnected in a voltage monitoring system according to another related art.

### DETAILED DESCRIPTION OF EMBODIMENTS

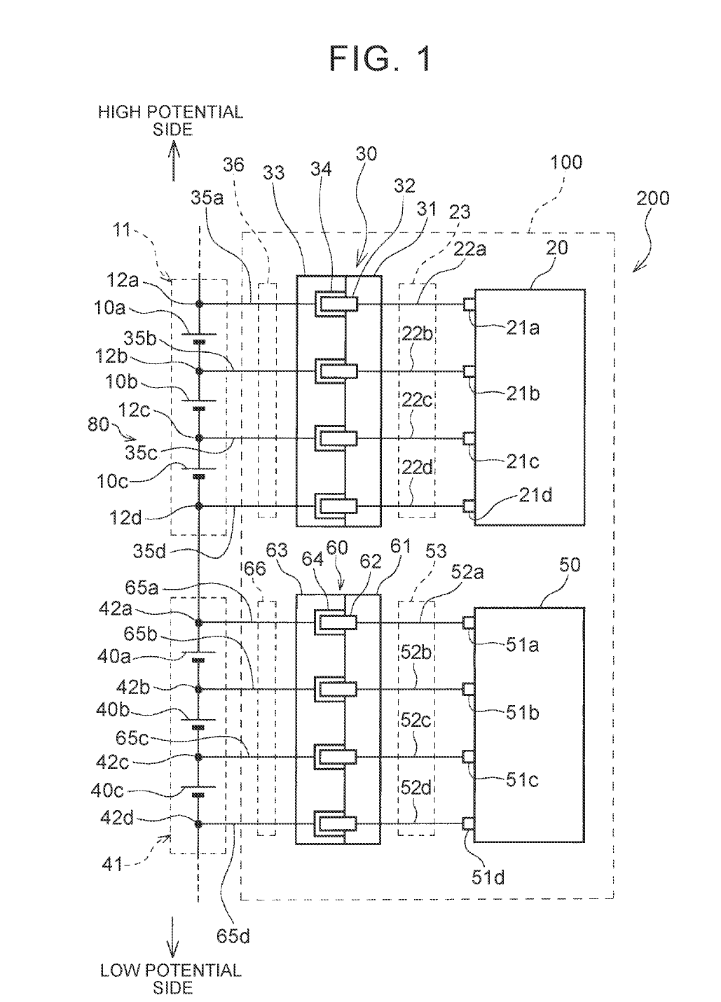

Hereinafter, a voltage monitoring system 100 according to an embodiment of the invention will be described with reference to the accompanying drawings. As shown in FIG. 1, the voltage monitoring system 100 according to the present embodiment monitors the voltage (cell voltage) of each of battery cells 10a to 10c, 40a to 40c of a battery 80 in which a first battery group 11 and a second battery group 41 are connected in series with each other. The first battery group 11 includes the plurality of serially connected battery cells 10a to 10c. The second battery group 41 includes the plurality of serially connected battery cells 40a to 40c. The voltage monitoring system 100 includes a first monitoring IC 20, a first connection line group 23, a first connector 30, a second monitoring IC 50, a second connection line group 53, and a second connector 60. The first monitoring IC 20 includes a plurality of input terminals 21a to 21d. The first connection line group 23 is formed of a plurality of connection lines 22a to 22d respectively connected to the input terminals 21a to 21d of the first monitoring IC 20. The first connector 30 is configured to connect or disconnect the first connection lines 22a to 22d of the first connection line group 23 to or from connection points 12a to 12d. The connection point 12b connects the positive electrode of the battery cell 10b of the first battery group 11 to the negative electrode of the battery cell 10a. The connection point 12c connects the positive electrode of the battery cell 10c of the first battery group 11 to the negative electrode of the battery cell 10b. The connection point 12a connects the negative electrode of a battery group connected to the high potential side of the first battery group 11 to the positive electrode of the battery cell 10a. The connection point 12d connects the positive electrode of the battery group connected to the low potential side of the first battery group 11 to the negative electrode of the battery cell 10c. The second monitoring IC 50 includes a plurality of input terminals 51a to 51d. The second connection line group 53 is formed of a plurality of second connection lines 52a to 52d respectively connected to the input terminals 51a to 51d of the second monitoring IC 50. The second connector 60 is configured to connect or disconnect the second connection lines 52a to 52d of the second connection line group 53 to or from connection points 42a to 42d. The connection point 42b connects the positive electrode of the battery cell 40b of the second battery group 41 to the negative electrode of the battery cell 40a. The connection point 42c connects the positive electrode of the battery cell 40c of the second battery group 41 to the negative electrode of the battery cell 40b. The connection point 42a connects the negative electrode of the battery group connected to the high potential side of the second battery group 41 to the positive electrode of the battery cell 40a. The connection point 42d connects the positive electrode of a battery group connected to the low potential side of the second battery group 41 to the negative electrode of the battery cell 40c. The battery 80 and the voltage monitoring system 100 constitute a battery system 200.

As shown in FIG. 1, the first connector 30 includes a first male connector 31 and a first female connector 33. The first male connector 31 has a plurality of male terminals 32. The first female connector 33 has a plurality of female terminals 34. The first connection lines 22a to 22d of the first connection line group 23 are respectively connected to the male terminals 32. The female terminals 34 are respectively connected to the connection points 12a to 12d by first cell-side connection lines 35a, 35b, 35c, 35d. The connection point 12b connects the positive electrode of the battery cell 10b of the first battery group 11 to the negative electrode of the battery cell 10a. The connection point 12c connects the positive electrode of the battery cell 10c of the first battery group 11 to the negative electrode of the battery cell 10b. The connection point 12a connects the negative electrode of the battery group connected to the high potential side of the first battery group 11 to the positive electrode of the battery cell 10a. The connection point 12d connects the positive electrode of the battery group connected to the low potential side of the first battery group 11 to the negative electrode of the battery cell 10c. The plurality of first cell-side connection lines 35a to 35d constitute a first cell-side connection line group 36. As the male terminals 32 of the first male connector 31 are respectively inserted into the female terminals 34 of the first female connector 33, the first connection line group 23 is electrically connected to the first cell-side connection line group 36. As a result, the connection point 12b that connects the positive electrode of the battery cell 10b of the first battery group 11 to the negative electrode of the battery cell 10a, the connection point 12c that connects the positive electrode of the battery cell 10c of the first battery group 11 to the negative electrode of the battery cell 10b, the connection point 12a that connects the negative electrode of the battery group connected to the high potential side of the first battery group 11 to the positive electrode of the battery cell 10a, and the connection point 12d that connects the positive electrode of the battery group connected to the low potential side of the first battery group 11 to the negative electrode of the battery cell 10c are electrically connected to the input terminals 21b, 21c, 21a, 21d of the first monitoring IC 20.

Similarly, the second connector 60 includes a second male connector 61 and a second female connector 63. The second male connector 61 has a plurality of male terminals 62. The second female connector 63 has a plurality of female terminals 64. The second connection lines 52a to 52d of the second connection line group 53 are respectively connected to the male terminals 62. The female terminals 64 are respectively connected to connection points 42a to 42d by second cell-side connection lines 65a, 65b, 65c, 65d. The connection point 42b connects the positive electrode of the battery cell 40b of the second battery group 41 to the negative electrode of the battery cell 40a. The connection point 42c connects the positive electrode of the battery cell 40c of the second battery group 41 to the negative electrode of the battery cell 40b. The connection point 42a connects the negative electrode of the battery group connected to the high potential side of the second battery group 41 to the positive electrode of the battery cell 40a. The connection point 42d connects the positive electrode of the battery group connected to the low potential side of the second battery group 41 to the negative electrode of the battery cell 40c. The plurality of second cell-side connection lines 65a to 65d constitute a second cell-side connection line group 66. As the male terminals 62 of the second male connector 61 are respectively inserted into the female terminals 64 of the second female connector 63, the second connection line group 53 is electrically connected to the second cell-side connection line group 66. As a result, the connection point 42b that connects the positive electrode of the battery cell 40b of the second battery group 41 to the negative electrode of the battery cell 40a, the connection point 42c that connects the positive electrode of the battery cell 40c of the second battery group 41 to the negative electrode of the battery cell 40b, the connection point 42a that connects the negative electrode of the battery group connected to the high potential side of the second battery group 41 to the positive electrode of the battery cell 40a, and the connection point 42d that connects the positive electrode of the battery group connected to the low potential side of the second battery group 41 to the negative electrode of the battery cell 40c are electrically connected to the input terminals 51b, 51c, 51a, 51d of the second monitoring IC 50.

As shown in FIG. 1, the battery cell 10c-side connection point 12d and the battery cell 40a-side connection point 42a are provided between the negative electrode of the low potential-side battery cell 10c of the first battery group 11 and the positive electrode of the high potential-side battery cell 40a of the second battery group 41, and the connection point 12d is connected to the input terminal 21d of the first monitoring IC 20 via the first cell-side connection line 35d, the first connector 30 and the first connection line 22d. The connection point 42a is connected to the input terminal 51a of the second monitoring IC 50 via the second cell-side connection line 65a, the second connector 60 and the second connection line 52a. Similarly, the connection point 12a between the positive electrode side of the high potential-side battery cell 10a of the first battery group 11 and the negative electrode of the high potential-side battery group (not shown) is connected to the input terminal 21a of the first monitoring IC 20 via the first cell-side connection line 35a, the first connector 30 and the first connection line 22a. The connection point 42d between the negative electrode side of the low potential-side battery cell 40c of the second battery group 41 and the positive electrode of the low potential-side battery group (not shown) is connected to the input terminal 51d of the second monitoring IC 50 via the second cell-side connection line 65d, the second connector 60 and the second connection line 52d.

As shown in FIG. 1, the first monitoring IC 20 is not electrically connected to the second monitoring IC 50. Therefore, the first monitoring IC 20 is electrically isolated from the second monitoring IC 50, and the first connection lines 22a to 22d of the first connection line group 23 are electrically isolated from the second connection lines 52a to 52d of the second connection line group 53.

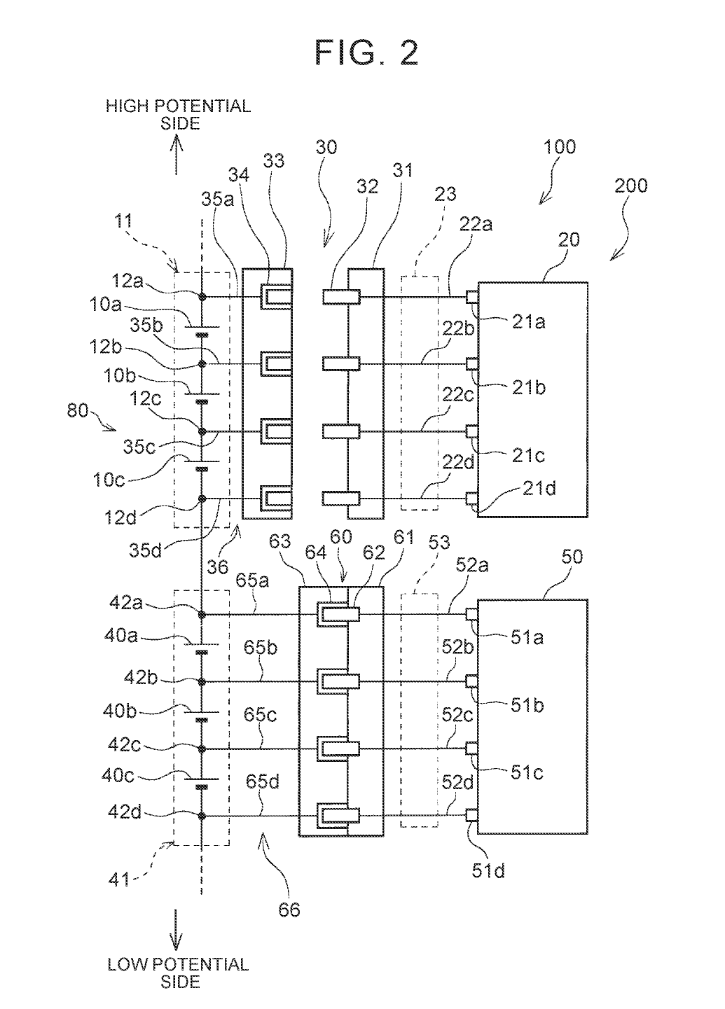

As shown in FIG. 2, as the first female connector 33 of the voltage monitoring system 100 described with reference to FIG. 1 is removed from the first male connector 31, the first connection line group 23 is disconnected from the first cell-side connection line group 36, with the result that the connection point 12b that connects the positive electrode of the battery cell 10b of the first battery group 11 to the negative electrode of the battery cell 10a, the connection point 12c that connects the positive electrode of the battery cell 10c of the first battery group 11 to the negative electrode of the battery cell 10b, the connection point 12a that connects the negative electrode of the battery group connected to the high potential side of the first battery group 11 to the positive electrode of the battery cell 10a, and the connection point 12d that connects the positive electrode of the battery group connected to the low potential side of the first battery group 11 to the negative electrode of the battery cell 10c are electrically isolated from the input terminals 21b, 21c, 21a, 21d of the first monitoring IC 20. On the other hand, because the second female connector 63 and the second male connector 61 remain connected to each other, the voltage of the second battery group 41 remains applied to the second connection line group 53 and the second monitoring IC 50. With the voltage monitoring system 100 according to the present embodiment, the first monitoring IC 20 is electrically isolated from the second monitoring IC 50 and the first connection line group 23 is electrically isolated from the second connection line group 53, so a potential does not sneak from the second battery group 41 to the first connection line group 23 and the first monitoring IC 20 via the second connection line group 53 and the second monitoring IC 50. For this reason, the male terminals 32 of the first male connector 31 have no potential although the male terminals 32 are disconnected and externally exposed, so it is possible to easily remove or connect the first female connector 33.

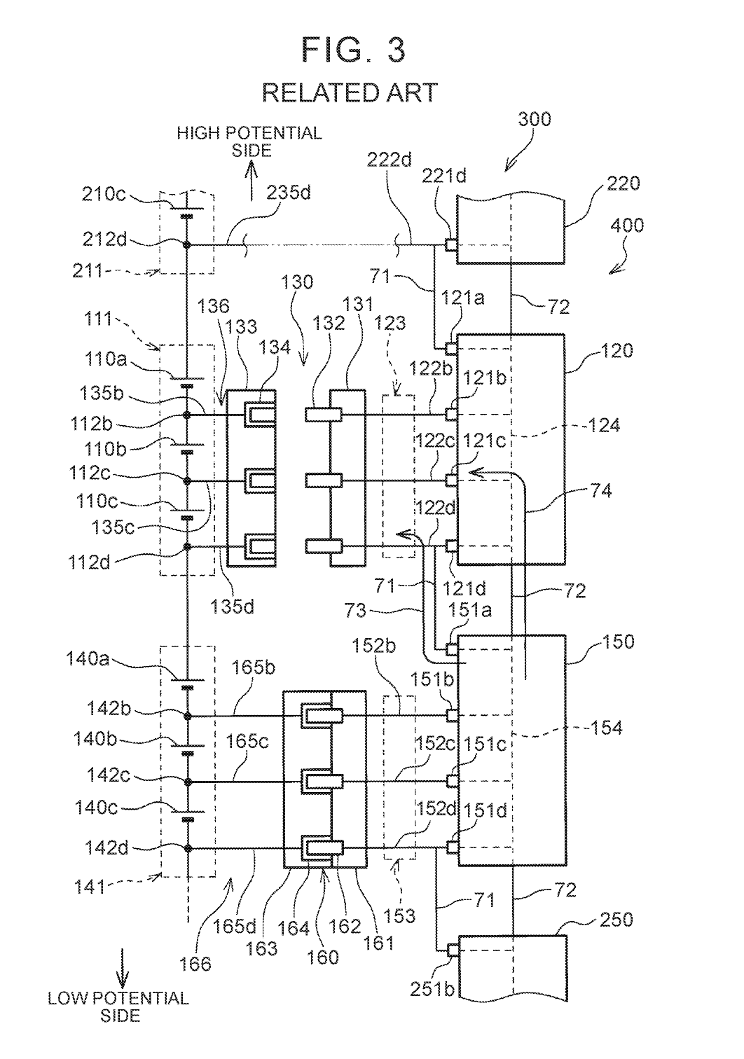

FIG. 3 shows a voltage monitoring system 300 according to a related art.

In the voltage monitoring system 300 according to this related art, only one connection point 112d is arranged between the negative electrode of a low potential-side battery cell 110c of a first battery group 111 and the positive electrode of a high potential-side battery cell 140a of a second battery group 141, and the connection point 112d is connected to an input terminal 121d of a first monitoring IC 120 via a first cell-side connection line 135d, a first connector 130 and a first connection line 122d and is also connected to an input terminal 151a of a second monitoring IC 150 by a connection line 71. Similarly, a connection point 212d between the positive electrode side of a high potential-side battery cell 110a of the first battery group 111 and the negative electrode of a high potential-side third battery group 211 is connected to an input terminal 221d of a third monitoring IC 220 via a third cell-side connection line 235d and a third connection line 222d, and a connection point 142d between the negative electrode side of a low potential-side battery cell 140c of the second battery group 141 and the positive electrode of a low potential-side battery group (not shown) is connected to an input terminal 151d of the second monitoring IC 150 via a second cell-side connection line 165d, a second connector 160 and a second connection line 152d and is also connected to an input terminal 251b of a fourth monitoring IC 250 by a connection line 71. The first monitoring IC 120 to the fourth monitoring IC 250 are connected in series with each other by connection lines 72. The input terminals 121a to 121d of the first monitoring IC 120 are connected by an internal wiring 124, and the input terminals 151a to 151d of the second monitoring IC 150 are connected by an internal wiring 154, and the internal wirings 124, 154 are respectively connected to the connection lines 72.

In this way, the connection point 112d between the negative electrode of the low potential-side battery cell 110c of the first battery group 111 and the positive electrode of the high potential-side battery cell 140a of the second battery group 141 is shared between the first monitoring IC 120 and the second monitoring IC 150. As a result, the first connection line group 123 and the first cell-side connection line group 136 that connect the first battery group 111 to the first monitoring IC 120 are respectively formed of three first connection lines 122b to 122d and three first cell-side connection lines 135b to 135d, the second connection line group 153 and the second cell-side connection line group 166 that connect the second battery group 141 to the second monitoring IC 150 are respectively formed of three second connection lines 152b to 152d and three second cell-side connection lines 165b to 165d, the first connector 130 is formed of the three sets of male terminals 132 and female terminals 134, and the second connector 160 is formed of the three sets of male terminals 162 and female terminals 164. The voltage monitoring system 300 and the battery groups 111, 141, 211 constitute a battery system 400.

However, in the thus configured voltage monitoring system 300 according to the related art, as shown in FIG. 3, when the first female connector 133 is removed, the potential of the second battery group 141, which is applied from the second battery group 141 to the input terminals 151b to 151d of the second monitoring IC 150 via the second cell-side connection line group 166, the second connector 160 and the second connection line group 153, is applied to the input terminal 151a of the second monitoring IC 150 via an internal wiring 154 of the second monitoring IC 150, and, as indicated by the arrow 73 in FIG. 3, the potential is applied from the input terminal 151a to one of the exposed male terminals 132 of the first male connector 131 via the connection line 71 and the first connection line 122d. As indicated by the arrow 74 in FIG. 3, the potential of the second battery group 141 is applied to the input terminals 121b to 121d via the internal wiring 154 of the second monitoring IC 150, the connection line 72 and an internal wiring 124 of the first monitoring IC 120, and the potential is applied from the input terminals 121b to 121d to the male terminals 132 of the first male connector 131. As a result, the male terminals 132 have a potential. For this reason, in connecting or removing the first female connector 133, the process of, for example, attaching an insulating cover is required in order for a worker not to touch the exposed male terminals 132.

As described above, in the voltage monitoring system 100 according to the present embodiment, different from the voltage monitoring system 300 according to the related art shown in FIG. 3, the first male connector 31 of the first connector 30 is connected to only the first monitoring IC 20, the first female connector 33 is connected to only the first battery group 11, the second male connector 61 of the second connector 60 is connected to only the second monitoring IC 50, and the second female connector 63 is connected to only the second battery group 41. As a result, the first connection line group 23 is electrically isolated from the second connection line group 53, and the monitoring ICs 20, 50 are electrically isolated from each other. For this reason, the disconnected and externally exposed male terminals 32 of the first male connector 31 have no potential when the first female connector 33 shown in FIG. 2 is removed, so it is possible to easily disconnect or connect the first female connector 33.

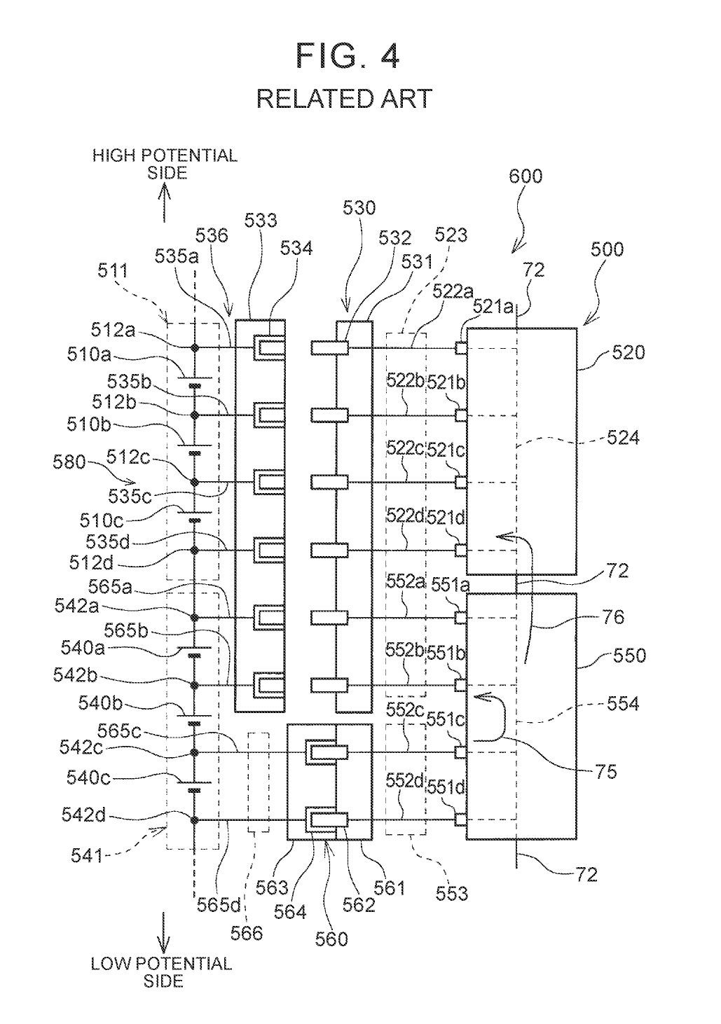

Next, a voltage monitoring system 500 according to another related art will be described with reference to FIG. 4. In the voltage monitoring system 500 according to this related art, reference numerals obtained by prefixing “5” to the reference numerals of portions described with reference to FIG. 1 and FIG. 2 are assigned to similar portions, five hundreds are used as the reference numerals, and the detailed description is omitted.

As shown in FIG. 4, the voltage monitoring system 500 monitors the voltage (cell voltage) of each of battery cells 510a to 510c of a first battery group 511 and battery cells 540a to 540c of a second battery group 541 as in the case shown in FIG. 1 and FIG. 2, and includes a first monitoring IC 520, a second monitoring IC 550, a first connector 530 and a second connector 560. The first connector 530 is configured to connect or disconnect six connection lines in total to or from six connection points in total. The six connection lines include a plurality of first connection lines 522a to 522d respectively connected to input terminals 521a to 521d of the first monitoring IC 520 and second connection lines 552a, 552b respectively connected to input terminals 551a, 551b of the second monitoring IC 550. The six connection points include connection points 512a to 512d each arranged on a side of the positive electrode or negative electrode of any one of the battery cells 510a to 510c of the first battery group 511 and connection points 542a, 542b arranged on the positive and negative electrode sides of the battery cell 540a of the second battery group 541. The six connection lines in total, that is, the first connection lines 522a to 522d and second connection lines 552a, 552b connected to the first male connector 531 of the first connector 530 constitute a first connection line group 523. Six cell-side connection lines, that is, first cell-side connection lines 535a to 535d that connect the first female connector 533 to the connection points 512a to 512d of the first battery group 511 and second cell-side connection lines 565a, 565b that connect the first female connector 533 to the connection points 542a, 542b of the second battery group 541 constitute a cell-side connection line group 536.

On the other hand, the second connector 560 is configured to connect or disconnect two connection lines to or from two connection points. The two connection lines include second connection lines 552c, 552d respectively connected to input terminals 551c, 551d of the second monitoring IC 550. The two connection points include a connection point 542c between the battery cell 540b and battery cell 540c of the second battery group 541 and a connection point 542d that connects the positive electrode of the battery group connected to the low potential side of the second battery group 541 to the negative electrode of the battery cell 540c. The second connection lines 552c, 552d constitute a second connection line group 553. The second cell-side connection lines 565c, 565d that connect a second female connector 563 to the connection points 542c, 542d of the second battery group 541 constitute a cell-side connection line group 566. As described with reference to FIG. 3, the terminals 521a to 521d of the first monitoring IC 520 are connected to one another by an internal wiring 524, the terminals 551a to 551d of the second monitoring IC 550 are connected to one another by an internal wiring 554, and the internal wirings 524, 554 are connected to each other by the connection line 72. The voltage monitoring system 500 and the battery groups 511, 541 constitute a battery system 600.

In the thus configured voltage monitoring system 500, the first male connector 531 of the first connector 530 is connected to the first monitoring IC 520 and the second monitoring IC 550 so as to span between the first monitoring IC 520 and the second monitoring IC 550, and the first female connector 533 is connected to the first battery group 511 and the second battery group 541 so as to span between the first battery group 511 and the second battery group 541, so the first connection line group 523 is not electrically isolated from the second connection line group 553. The monitoring ICs 520, 550 are also not electrically isolated from each other. For this reason, when the first female connector 533 is removed from the first male connector 531, as indicated by the arrow 75 in FIG. 4, the potential of part of the second battery group 541 is applied from the terminals 551c, 551d of the second monitoring IC 550, connected to part of the second battery group 541 by the second connector 560 to one of the exposed male terminals 532 of the first male connector 531 via the internal wiring 554 of the second monitoring IC 550, the input terminals 551a, 551b and the connection lines 552a, 552b. As a result, the male terminals 532 have a potential. As indicated by the arrow 76 in FIG. 4, the potential of part of the second battery group 541 is applied to the exposed male terminals 532 of the first male connector 531 via the internal wiring 554 of the second monitoring IC 550, the connection line 72, the internal wiring 524 of the first monitoring IC 520, the input terminals 521a to 521d of the first monitoring IC 520 and the connection lines 522a to 522d. As a result, the male terminals 532 have a potential. For this reason, in connecting or removing the first female connector 533, the process of, for example, attaching an insulating cover is required in order for a worker not to touch the exposed male terminals 532.

The voltage monitoring system 100 according to the present embodiment is different from the voltage monitoring system 500 according to the related art described with reference to FIG. 4, that is, the configuration that the first male connector 531 of the first connector 530 is connected to the first monitoring IC 520 and the second monitoring IC 550 so as to span between the first monitoring IC 520 and the second monitoring IC 550, the first female connector 533 is connected to the first battery group 511 and the second battery group 541 so as to span between the first battery group 511 and the second battery group 541, and the first connection line group 523 and the second connection line group 553 are not electrically isolated from each other. In the voltage monitoring system 100 according to the present embodiment, the first male connector 31 of the first connector 30 is connected to only the first monitoring IC 20, the first female connector 33 is connected to only the first battery group 11, the second male connector 61 of the second connector 60 is connected to only the second monitoring IC 50, the second female connector 63 is connected to only the second battery group 41, the first connection line group 23 is electrically isolated from the second connection line group 53, and the monitoring ICs 20, 50 are electrically isolated from each other. For this reason, in the voltage monitoring system 100 according to the present embodiment, the disconnected and externally exposed male terminals 32 of the first male connector 31 have no potential when the first female connector 33 shown in FIG. 2 is removed, so it is possible to easily remove or connect the first female connector 33.

What is claimed is:

1. A voltage monitoring system that monitors each of cell voltages of a battery in which a first battery group and a second battery group are connected in series with each other, the first battery group including a plurality of connected battery cells, the second battery group including a plurality of connected battery cells, the voltage monitoring system comprising:
a first monitoring IC including a plurality of input terminals;
a first connection line group including first connection lines respectively connected to the input terminals of the first monitoring IC;
a first connector configured to connect or disconnect the first connection lines of the first connection line group to or from first connection points each arranged on a positive electrode-side or negative electrode-side of any one of the battery cells of the first battery group;
a second monitoring IC including a plurality of input terminals, the second monitoring IC being electrically isolated from the first monitoring IC;
a second connection line group including second connection lines respectively connected to the input terminals of the second monitoring IC, the second connection line group being electrically isolated from the first connection line group; and
a second connector configured to connect or disconnect the second connection lines of the second connection line group to or from second connection points each arranged on a side of a positive electrode or negative electrode of any one of the battery cells of the second battery group.

2. The voltage monitoring system according to claim 1, wherein
the first connector includes a first male connector having a plurality of male terminals and a first female connector having a plurality of female terminals, and
the second connector includes a second male connector having a plurality of male terminals and a second female connector having a plurality of female terminals.

3. The voltage monitoring system according to claim 2, wherein
the first connection lines of the first connection line group are respectively connected to the male terminals of the first connector,
the first connection points for the battery cells of the first battery group are respectively connected to the female terminals of the first connector by a first cell-side connection line group,
the second connection lines of the second connection line group are respectively connected to the male terminals of the second connector, and
the second connection points for the battery cells of the second battery group are respectively connected to the female terminals of the second connector by a second cell-side connection line group.

4. The voltage monitoring system according to claim 3, wherein
the first connection point on a low potential-side battery cell side and the second connection point on a high potential-side battery cell side are provided between the negative electrode of the low potential-side battery cell of the first battery group and the positive electrode of the high potential-side battery cell of the second battery group,
the first connection point is connected to one of the input terminals of the first monitoring IC via a first cell-side connection line of the first cell-side connection line group, the first connector and one of the first connection lines, and
the second connection point is connected to one of the input terminals of the second monitoring IC via a second cell-side connection line of the second cell-side connection line group, the second connector and one of the second connection lines.
